(19) United States
(12) Patent Application Publication
(10) Pub. No.: US 2002/0076936 A1
(43) Pub. Date: Jun. 20, 2002

(54) METHOD OF FABRICATING SEMICONDUCTOR INTEGRATED CIRCUIT DEVICE AND THE SEMICONDUCTOR INTEGRATED CIRCUIT DEVICE

(76) Inventor: ERI IGUCHI, FUCHU (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/425,303

(22) Filed: Oct. 25, 1999

(30) Foreign Application Priority Data
Oct. 23, 1998 (JP) 10-301958

(51) Int. Cl. H01L 21/302; H01L 21/461

(52) U.S. Cl. 438/710

(57) ABSTRACT

When an Ir-based conductor film, particularly an IrO₂ film, is patterned by dry etching using a resist mask, reaction products having a low vapor pressure are likely to be left on the side surface of a pattern. This invention is directed to prevent the reaction products from remaining on the side surface and moreover, to form a miniature pattern with high dimensional accuracy. When an IrO₂ film 55 is patterned by dry etching using a resist mask 56, an etching gas comprising a chlorine gas as a main component and containing oxygen as an additional gas is used in order to lower a selection ratio of the IrO₂ film 55 to the resist, and a side wall adhesion film 57 adhering to the side wall of the pattern is eliminated, by recessing the side wall of the resist mask 56.

### BACKGROUND OF THE INVENTION

This invention relates to a fabrication technology of a semiconductor integrated circuit device. More specifically, it relates to a technology which will be effective when it is applied to a process for forming an electrode of a capacitance device (capacitor) by etching an electrically conductive thin film formed of Ir (iridium) or its oxide (IrO₂) as a main constituent element.

Research and development has been made in order to put the latest Gbit (Giga-bit) DRAM (Dynamic Random Access Memory), that has attained scale-down and high integration density to the best possible extent, and Fe (Ferroelectric) RAM (Random Access Memory) that is expected to substitute existing semiconductor memories such as DRAM and flash memories, into practical application. These new memories use a high dielectric or ferroelectric substance such as PZT (PbZrₓ Ti₁₋ₓ O₃), PLT (PbLaₓ Ti₁₋ₓ O₃), PLZT, PbTiO₃, SrTiO₃, BaTiO₃, BST (Baₓ Sr₁₋ₓ TiO₃), SBT (SrBi₂ Ta₂ O₉), and so forth, for a capacitance insulation film of a capacitance device (capacitor) that constitutes a part of a memory cell. Since the high dielectric or ferroelectric substance contains a large amount of oxygen having high reactivity, it characteristics are likely to get deteriorated by heat during a fabrication process with the result of the drop of the production yield and retention characteristics (data retention characteristics). Therefore, an electrically conductive material that is made of a platinum group metal or its oxide as a main component, and has high affinity with such a high dielectric or ferroelectric substance, such as Pt (platinum), Ru (ruthenium) or Ir, is used for the electrode of the capacitance device using the high dielectric or ferroelectric substance (refer to “Applied Physics”, Vol. 64, No. 12, p1188-1197 (Dec. 10, 1995), Vol. 65, No. 11, p1106-1113 (Nov. 10, 1996) and Vol. 66, No. 11, p1210-1213 (Nov. 10, 1997), published by the Japan Society of Applied Physics, and “Monthly Semiconductor World”, Vol. 17, No. 7, p78-105 (Jun. 20, 1998) published by K. K. Press Journal).

To form the capacitance device using the high dielectric or ferroelectric substance and the electrically conductive material, a first thin film of a platinum group metal (or its oxide), a high dielectric or ferroelectric film and a second thin film of the platinum group metal(or its oxide) are serially deposited over an insulation film formed on a semiconductor substrate (wafer). Next, the thin films of these three layers are patterned into a predetermined shape by dry etching with a photoresist film as a mask. An anisotropic etching method such as RIE (Reactive Ion Etching) is generally employed as the etching method. A halogen gas such as chlorine (Cl₂) or a gas obtained by adding an inert gas such as Ar (argon) to the chlorine gas is generally used as the etching gas (refer to Proceedings of 1991 Fall Conference of The Society of Applied Physics, 9p-ZF-17p516).

When the thin film of the platinum group metal or its oxide is patterned by dry etching, there occur the problems that large amounts of reaction products having a low vapor pressure adhere to the side wall of the pattern, and that a desired pattern cannot be obtained with high accuracy, as it is well known in the art. Various methods have therefore been proposed in order to solve these problems.

For example, Japanese Patent Laid-Open No. 17806/1996 (Matsumoto et al.) has pointed out that when the Pt film or the BST film is dry etched with the photoresist film as the mask, the following two problems occur.

(1) Since the etching rate of the resist is by far higher than that of Pt and BST, the resist is fully etched during etching of Pt and BST. A thick film resist must be used to solve this problem. When the thick film resist is used, however, resolution drops, so that the formation of a miniature pattern becomes extremely difficult.

(2) Since the etching rate of a silicon oxide film as an underlying insulation film is by far higher than that of Pt and BST, the underlying insulation film is fully etched during etching of Pt and BST. As a result, circuit devices below the underlying insulation film are etched, too.

To cope with the problem (1), the reference described above uses chloroform (or a mixed gas of chloroform/chlorine or chloroform/HBr) and conducts etching in a low etching pressure region of 1 to 5 Pa. In this way, the reference improves an etching selection ratio to the resist, increases the etching rate of Pt and BST, and improves through-put.

To cope with the problem (2), the reference uses a mixed gas of HBr (hydrogen bromide) and oxygen for dry etching of the Pt film/BST film/Pt film deposited over the silicon oxide film, and improves the etching selection ratio with respect to the underlying silicon oxide film.

To avoid the drop of pattern accuracy resulting from adhesion of large amounts of reaction products having a low vapor pressure to the pattern side wall during dry etching of the Pt film and the PZT film with the chlorine gas containing Ar, Japanese Patent Laid-Open No. 98162/1998 (Serial No. 08/935,033 Yunogami et al.) conducts etching using a photoresist film, the top of which is circular around its outer periphery, then conducts over-etching to a suitable level and completely removes the side wall adhesion film remaining on the side surface of the pattern. The photoresist film the top of which is circular around its outer periphery is formed by exposing and developing a benzophenone-based novolak resist and heat-curing the resin by irradiating ultraviolet rays, whenever necessary.

Etching by-products having high boiling points, that are formed by the reaction between a halogen gas and Pt during dry etching of the Pt film by using the halogen gas, adhere again to the side wall of the pattern and deteriorate the pattern profile. To solve this problem, Japanese Patent Laid-Open No. 68094/1998 (Kin et al.) discloses a method that uses an etching gas comprising a first gas comprising in turn a halogen gas (C1₂, F₂, Br₂,I₂) and/or a halide gas (chloride, fluoride, bromide, iodide), a second gas comprising a carbon oxide-based gas (CO, CO₂, carbonyl (=CO) compound), a hydrocarbon gas (benzene, cyclopentadiene, toluene, butadiene), a nitrogen oxide-based gas (NO, NO₂) or a nitrogen-based gas (ammonia) (and/or a third gas comprising oxygen, nitrogen a CF-based gas, a steam or an inert gas).

### SUMMARY OF THE INVENTION

The present inventor has developed a capacitance device using a ferroelectric material that can be applied to the memory cell of large capacity DRAM and FeRAM. The inventor has examined the possibility of using PZT, BST, PLT, PLZT or SBT having a perovskite structure or a structure equivalent to the perovskite structure, for the ferroelectric material, particularly PZT that can be shaped into the film at a relatively low temperature (approx. 600° C.). As for the electrode material, the inventor has examined the possibility of using the platinum group metals and their oxides, such as Ir, IrO₂, Pt, Ru and RuO₂, particularly Ir and IrO₂ for the top electrode material, because they have the effect of preventing degradation of PZT and have high adhesion with PZT.

Among the platinum group metals and their oxides, however, the Ir-based conductive films such as Ir and IrO₂, in particular, have low chemical reactivity, and the vapor pressure of their reaction products by dry etching is low. Therefore, when these films are etched with the photoresist as the mask, large amounts of the reaction products are likely to adhere to the side wall of the resist. The IrO₂ film, in particular, has a low etching rate, and its reaction products adhering to the side wall of the resist during etching cannot easily be removed by the ions. Thus, there remain the problems that the pattern having desired accuracy cannot be obtained by etching using the resist mask and that wet washing must be conducted to remove the reaction products after etching.

An etching method using a hard mask such as a silicon oxide film or a metal film in place of the resist mask for etching the conductor film producing large amounts of the side wall adhesion film is available. For example, 1995 No. 56 Proceedings of the Society of Applied Physics, No. 2, 26a-ZT-4, reports that the Pt film can be processed into the taper shape and etching devoid of the side wall adhesion film can be done during dry etching of the Pt film with the silicon oxide film, that is etched into a predetermined pattern, as the mask, and an Ar gas to which oxygen is added is used as the etching gas. Also, Japanese Patent Laid-Open No. 89662/1993 discloses a method of forming an excellent Pt pattern free from a side wall adhesion film, by etching the Pt film with a Ti film, that is etched into a predetermined pattern, as the mask.

However, the method that uses the hard mask needs a process step of dry etching the silicon oxide film and the metal film deposited on the conductor film into the hard mask, and the number of process steps becomes greater than when the resist mask is used. The hard mask must be heated to a high temperature in some cases during etching, and deterioration of the underlying high dielectric or ferroelectric film becomes the problem. Furthermore, it is difficult from time to time to remove the hard mask after etching is completed.

It is therefore an object of the present invention to provide a technology that makes it possible to form a miniature pattern with high dimensional accuracy without leaving reaction products having a low vapor pressure on the side surface of a pattern, when an Ir-based conductor film, particularly an IrO₂ film, is patterned by dry etching with a resist mask.

The above and other objects and novel features of the present invention will become more apparent from the following description of the specification with the accompanying drawings.

A typical invention among the inventions disclosed herein may be briefly summarized as follows.

When an IrO₂ film is patterned by dry etching with a resist mask, a method of fabricating a semiconductor integrated circuit device according to the present invention uses an etching gas, that comprises a chlorine gas as a main component and contains oxygen as an additional gas, so as to lower a selection ratio of the IrO₂ film to the resist, and to recess the side wall of the resist mask, and thus removes the side wall adhesion film adhering otherwise to the pattern side wall.

Other representative aspects of the invention may be also summarized as follows.

1. A method of fabricating a semiconductor integrated circuit device according to the present invention includes the following step:

applying a dry etching treatment to a first film formed of Ir or IrO₂ as a main constituent element over a first main plane of a semiconductor wafer having a photoresist film formed and patterned thereon, in a gas atmosphere comprising a chlorine gas as a main component of an etching gas and containing oxygen as an additional gas.

2. In the paragraph 1, the first film is a film formed of IrO₂ as a main constituent element.

3. In the paragraph 2, the method further comprises a step of removing the side wall adhesion film adhering to the side wall of the pattern during the dry etching treatment, during the dry etching treatment or during a gaseous phase process subsequent to the dry etching treatment.

4. A method of fabricating a semiconductor integrated circuit device according to the present invention comprises the following steps:

(a) applying a dry etching treatment to a first film formed of Ir or IrO₂ as a main constituent element on a first main plane of a semiconductor wafer having an etching-resistant mask layer formed and patterned thereon, in a gas atmosphere containing a chlorine gas as a main component of an etching gas; and

(b) monitoring light emission from Ir during the process step described above, judging the end point of etching and stopping the etching operation on the basis of this judgement.

5. In the paragraph 4, the underlying film of the first film is a dielectric film formed of a high dielectric substance or a ferroelectric substance having a perovskite structure or a structure equivalent to the perovskite structure as a main component.

6. In the paragraph 5, the dielectric film is made of BST, PZT, PLT, PLZT or SBT as a main component.

7. In the paragraph 6, the etching-resistant mask layer is a photoresist layer.

8. In the paragraph 7, the wavelength of light emission to be monitored is 351 nm.

9. A method of fabricating a semiconductor integrated circuit device according to the present invention comprises the following steps:

(a) applying a dry etching treatment to a first film formed of a platinum group metal or its oxide as a main constituent element, over a first main plane of a semiconductor wafer having a photoresist film formed and patterned thereon, in a gas atmosphere containing a chlorine gas as a main component of an etching gas and oxygen as an additional gas; and

(b) applying over-etching to the first film by removing a side wall adhesion film adhering during the first etching step while an underlying second film formed of a material different from that of the first film is being etched beyond the first film.

10. In the paragraph 9, the over-etching amount is at least 50%.

11. In the paragraph 10, the gas atmosphere at the time of over-etching contains a chlorine gas as a main component of the etching gas and oxygen as an additional gas.

12. In the paragraph 11, the first film is formed of Pt, Ru, RuO₂, Ir or IrO₂ as a main constituent element.

13. In the paragraph 12, the gas atmosphere at the time of over-etching is substantially the same as the gas atmosphere of the step (a) for applying the dry etching treatment.

14. A method of fabricating a semiconductor integrated circuit device according to the present invention comprises the step of:

applying a dry etching treatment to a first film containing those components which are likely to invite side wall adhesion at the time of etching, over a first main plane of a semiconductor wafer having a photoresist formed and patterned thereon, in a gas atmosphere containing a chlorine gas as a main component of an etching gas, and a gas having a function of lowering a selection ratio to a resist, as an additional gas.

15. In the paragraph 14, the first film is a film formed of a platinum group metal, its oxide, its complex oxide, a perovskite type compound, or a high dielectric substance or ferroelectric substance having a structure equivalent to the pervovskite structure, as a main constituent element.

16. In the paragraph 15, the gas having the function of lowering the selection ratio to the resist is oxygen.

17. In the paragraph 16, the gas atmosphere further contains an inert gas.

18. A method of fabricating a semiconductor integrated circuit device according to the present invention comprises the steps of:

(a) applying a dry etching treatment to a first film containing those materials which are likely to invite side wall adhesion during etching, over a first main plane of a semiconductor wafer having a photoresist film formed and patterned thereon, in a gas atmosphere containing a chlorine gas as a main component of an etching gas and a gas having a function of lowering a selection ratio to a resist as an additional gas; and

(b) applying over-etching to the first film by removing a side wall adhesion film adhering during the etching step of the first film, while an underlying second film formed of a material different from that of the first film is being etched beyond the first film.

19. In the paragraph 18, the over-etching amount is at least 50%.

20. In the paragraph 19, the gas atmosphere at the time of over-etching contains a chlorine gas as a main component of the etching gas and oxygen as an additional gas.

21. In the paragraph 20, the gas atmosphere during over-etching is substantially the same as the gas atmosphere of the step (a) of applying the dry etching treatment.

22. A semiconductor integrated circuit device according to the present invention comprises:

(a) a semiconductor substrate region having a first main plane;

(b) a bottom electrode for constituting a part of a capacitor of a memory cell formed on the first main plane either directly or through at least one film;

(c) an information storage dielectric layer formed of a high dielectric substance or a ferroelectric substance, for constituting a part of the capacitor of the memory cell formed on the bottom electrode; and

(d) a top electrode formed of Ir or IrO₂, for constituting another part of the capacitor of the memory cell formed on the information storage dielectric layer;

wherein the pattern side surface of the top electrode has a taper expanding downward, and angle of inclination of its slope is not greater than 80°.

23. In the paragraph 22, the information storage dielectric layer is formed of a high dielectric substance or a ferroelectric substance having a perovskite structure or a structure analogous to the perovskite structure.

24. In the paragraph 23, the angle of inclination of the slope is not greater than 75°.

25. In the paragraph 24, the information storage dielectric layer is formed of PZT, PLT and PLZT.

26. A method of fabricating a semiconductor integrated circuit device according to the present invention comprises the steps of:

(a) applying a dry etching treatment to a first film formed of a platinum group metal or its oxide as a main constituent element, over a first main plane of a semiconductor wafer having a photoresist film formed and patterned thereon, in a gas atmosphere containing a chlorine gas as a main component of an etching gas; and

(b) applying over-etching to the first film by removing a side wall adhesion film adhering during the etching step of the first film while an underlying second film formed of a material different from that of the first film is being etched beyond the first film in a gas atmosphere containing a chlorine gas as a main component and oxygen as an additional gas.

27. A method of fabricating a semiconductor integrated circuit device according to the present invention comprises the steps of:

(a) applying a dry etching treatment to a first film formed of a platinum group metal or its oxide as a main constituent element over a first main plane of a semiconductor wafer having a photoresist film formed and patterned thereon, in a gas atmosphere containing a chlorine gas and oxygen added thereto; and

(b) applying over-etching to the first film by removing a side wall adhesion film adhering during the etching step of the first film while an underlying second film formed of a material different from that of the first film, beyond the first film.

28. A method of fabricating a semiconductor integrated circuit device according to the present invention comprises the step of:

applying a dry etching treatment to a first film formed of Ir or IrO₂ as a main constituent element, over a first main plane of a semiconductor wafer having a photoresist film formed and patterned thereon, in a gas atmosphere containing a chlorine gas as an etching gas and oxygen added thereto.

29. A semiconductor integrated circuit device according to the present invention comprises:

(a) a semiconductor substrate region having a first main plane;

(b) a bottom electrode formed of Ru or RuO₂, for constituting a part of a capacitor of a memory cell formed on the first main plane either directly or through at least one film;

(c) an information storage dielectric layer formed of PZT or a ferroelectric substance equivalent to PZT, for constituting a part of the capacitor of the memory cell formed on the bottom electrode; and

(d) a top electrode formed of Ir or IrO₂, for constituting a part of the capacitor of the memory cell formed on the information storage dielectric layer.

30. A method of fabricating a semiconductor integrated circuit device according to the present invention comprises the steps of:

(a) forming a first film containing those components which are likely to invite adhesion of reaction products on the side wall of a pattern during a dry etching treatment, over a main plane of a semiconductor substrate;

(b) forming an etching-resistant mask layer patterned into a predetermined shape, on the first film; and

(c) dry etching the first film in a gas atmosphere of an etching gas containing a chlorine gas and a gas generating oxygen radicals in plasma.

31. In the paragraph 30, the gas that generates the oxygen radicals in the plasma is oxygen or ozone.

32. In the paragraph 30, the first film contains Ir or its oxide.

33. In the paragraph 32, the method further includes a step of monitoring light emission from Ir during the dry etching step, judging the end point of etching and stopping etching on the basis of the judgement.

34. In the paragraph 30, the etching-resistant mask layer is a photoresist film patterned into a predetermined shape.

35. A method of fabricating a semiconductor integrated circuit device according to the present invention comprises the steps of:

(a) forming a first film containing those components which are likely to invite adhesion of reaction products to the side wall of a pattern during a dry etching treatment, over a main plane of a semiconductor substrate;

(b) forming an etching-resistant mask layer patterned into a predetermined shape, over the first film;

(c) dry etching the first film in an atmosphere of an etching gas containing a chlorine gas; and

(d) over-etching an underlying film of the first film in an atmosphere of an etching gas containing a chlorine gas and a gas which generates oxygen radicals in plasma.

36. In the paragraph 35, the first film contains Ir or its oxide, and the underlying film is formed of a high dielectric substance or a ferroelectric substance having a perovskite structure or a structure equivalent to the perovskite structure.

37. In the paragraph 36, the high dielectric substance or the ferroelectric substance is formed of a complex oxide containing Pb.

38. A method of fabricating a semiconductor integrated circuit device according to the present invention comprises the steps of:

(a) forming a first film containing those components which are likely to invite adhesion of reaction products to the side wall of a pattern during a dry etching treatment, over a main plane of a semiconductor substrate;

(b) forming a photoresist film patterned into a predetermined shape over the first film; and

(c) dry etching the first film in an atmosphere of an etching gas containing a chlorine gas and a gas that lowers a selection ratio of the first film to the resist.

39. A method of fabricating a semiconductor integrated circuit device according to the present invention comprises the steps of:

(a) forming a first conductor film over a main plane of a semiconductor substrate;

(b) forming an insulating film formed of a high dielectric substance or a ferroelectric substance over the first conductor film;

(c) forming a second conductor film containing those components which are likely to invite adhesion of reaction products to the side wall of a pattern during the dry etching treatment, over the insulating film;

(d) forming a photoresist film patterned into a predetermined shape, over the second conductor film;

(e) dry etching the second conductor film using the photoresist film as the mask in an atmosphere of an etching gas containing a chlorine gas and a gas generating oxygen radicals in plasma; and

(f) forming a bottom electrode comprising the first conductor film, a capacitance insulation film comprising the insulation film and a top electrode comprising the second conductor film, by patterning the insulating film and the first conductor film below the second conductor film.

40. In the paragraph 39, the second conductor film contains Ir or its oxide, and the insulation film is formed of a high dielectric substance or a ferroelectric substance having a perovskite structure or a structure equivalent to the perovskite structure.

41. In the paragraph 40, the high dielectric substance or the ferroelectric substance is formed of PZT, PLT or PLZT.

42. In the paragraph 39, the first conductor film contains Ir or its oxide, or Ru or its oxide, or Pt.

43. In the paragraph 39, the method further comprises a step of over-etching the insulation film with the photoresist film as the mask, in an atmosphere of the etching gas, after the second conductor film is dry etched.

44. In the paragraph 39, the capacitance device constitutes a part of a memory cell of a DRAM.

45. In the paragraph 39, the capacitance device constitutes a part of a memory cell of FeRAM.

46. In the paragraph 45 or 46, the capacitance device is formed over a MISFET forming another part of the memory cell.

### BRIEF DESCRIPTION OF THE DRAWINGS

FIG. 1 is a sectional view of principal portions of a semiconductor substrate, and shows a dry etching method of an IrO₂ film according to the embodiment 1 of the present invention;

FIG. 2 is a sectional view of principal portions of a semiconductor substrate, and shows a dry etching method of an IrO₂ film according to the embodiment 1 of the present invention;

FIG. 3 is a schematic view of principal portions of a magnetron RIE etcher used in the embodiment 1 of the present invention;

FIG. 4(a) is a sectional view of principal portions of a semiconductor substrate, and shows a dry etching method of an IrO₂ film according to the embodiment 1 of the present invention;

FIG. 4(b) is a sectional view of principal portions of a semiconductor substrate, and shows a dry etching method in a Comparative Example;

FIG. 5(a) is a sectional view of a semiconductor substrate, and shows a dry etching method of an IrO₂ film according to the embodiment 1 of the present invention;

FIG. 5(b) is a sectional view of principal portions of a semiconductor substrate, and shows a dry etching method in a Comparative Example;

FIG. 6 is a graph showing dependence of etching properties on an oxygen flow rate;

FIG. 7 is a graph showing data of light emission spectra during etching of an IrO₂ film;

FIG. 8 is a sectional view of principal portions of a semiconductor substrate, and shows a method of fabricating a DRAM according to the embodiment 2 of the present invention;

FIG. 9 is a sectional view of principal portions of a semiconductor substrate, and shows a method of fabricating a DRAM according to the embodiment 2 of the present invention;

FIG. 10 is a sectional view of principal portions of a semiconductor substrate, and shows a method of fabricating a DRAM according to the embodiment 2 of the present invention;

FIG. 11 is a sectional view of principal portions of a semiconductor substrate, and shows a method of fabricating a DRAM according to the embodiment 2 of the present invention;

FIG. 12 is a sectional view of principal portions of a semiconductor substrate, and shows a method of fabricating a DRAM according to the embodiment 2 of the present invention;

FIG. 13 is a sectional view of principal portions, and shows a method of fabricating a DRAM according to the embodiment 2 of the present invention;

FIG. 14 is a sectional view of principal portions of a semiconductor substrate, and shows a method of fabricating a DRAM according to the embodiment 2 of the present invention;

FIG. 15 is a sectional view of principal portions of a semiconductor substrate, and shows a method of fabricating a DRAM according to the embodiment 2 of the present invention;

FIG. 16 is a sectional view of principal portions of a semiconductor substrate, and shows a method of fabricating a DRAM according to the embodiment 2 of the present invention;

FIG. 17 is a sectional view of principal portions of a semiconductor substrate, and shows a method of fabricating a DRAM according to the embodiment 2 of the present invention;

FIG. 18 is a sectional view of principal portions of a semiconductor substrate, and shows a method of fabricating a DRAM according to the embodiment 2 of the present invention;

FIG. 19 is a sectional view of principal portions of a semiconductor substrate, and shows a method of fabricating a DRAM according to the embodiment 2 of the present invention;

FIG. 20 is a sectional view of principal portions of a semiconductor substrate, and shows a method of fabricating a FeRAM according to the embodiment 3 of the present invention;

FIG. 21 is a sectional view of principal portions of a semiconductor substrate, and shows a method of fabricating a FeRAM according to the embodiment 3 of the present invention;

FIG. 22 is a sectional view of principal portions of a semiconductor substrate, and shows a method of fabricating a FeRAM according to the embodiment 3 of the present invention;

FIG. 23 is a sectional view of principal portions of a semiconductor substrate, and shows a method of fabricating a FeRAM according to the embodiment 3 of the present invention;

FIG. 24 is a sectional view of principal portions of a semiconductor substrate, and shows a method of fabricating a FeRAM according to the embodiment 3 of the present invention;

FIG. 25 is a sectional view of principal portions of a semiconductor substrate, and shows a method of fabricating a FeRAM according to the embodiment 3 of the present invention; and

FIG. 26 is a sectional view of principal portions of a semiconductor substrate, and shows a method of fabricating a FeRAM according to the embodiment 3 of the present invention.

### DESCRIPTION OF THE PREFERRED EMBODIMENTS

Hereinafter, preferred embodiments of the present invention will be explained in detail with reference to the accompanying drawings. Incidentally, like reference numerals will be assigned to components with the same function throughout the entire drawings, and the repetition of explanation on similar components will be omitted. Furthermore, the explanation on a similar or same portion will not be repeated unless otherwise specifically necessary.

In the embodiments that follow, the explanation will be made by dividing each embodiment into a plurality of sections or into a plurality of embodiment forms, whenever necessary. Unless specifically noted otherwise, however, these divided sections or embodiment forms are in no way irrelevant to one another, but one constitutes a modification of a part, or the whole part, of another, and has the relationship of detailed or supplementary explanation of another.

In the embodiments that follow, numerals of components (inclusive of the number of pieces, numerical values, ranges, and so forth) are in no way restricted to specific numbers but may be greater or smaller than the specific numbers unless stipulated clearly and unless theoretically self-explanatory. Needless to say, constituent elements of the embodiments (inclusive of element steps, and so forth) are not always essentially necessary unless clearly stipulated as being necessary and unless believed as being essentially necessary from principle.

In the embodiments that follow, the shapes, the positional relationship, etc, of the constituent elements include those shapes and relationship, etc, which are substantially approximate or equivalent, unless clearly stipulated otherwise and unless believed as being clearly different from principle. This also holds true of the numerical values and the ranges described above.

Unless stipulated otherwise, the term “semiconductor integrated circuit device” used herein means not only those semiconductor devices which are fabricated particularly on a single crystal silicon substrate, but also those which are fabricated on other substrates such as a SOI (Silicon On Insulator) substrate and a substrate for producing a TFT (Thin Film Transistor) liquid crystal.

Embodiment 1:

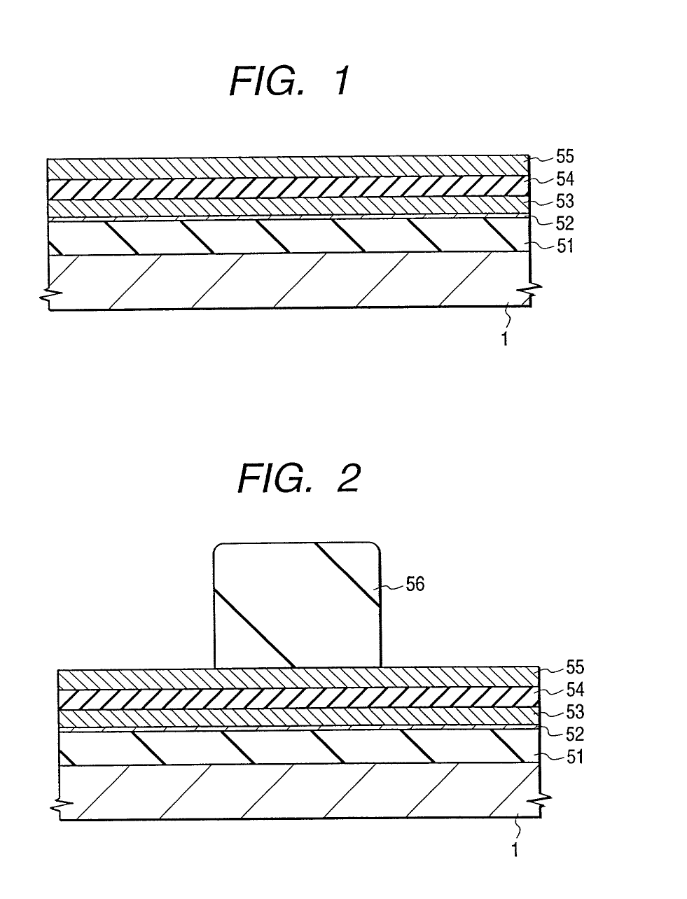

A dry etching method of an IrO₂ film according to this embodiment will be explained with reference to FIGS. 1 to 7. A silicon oxide film 51 is deposited over a main plane of a semiconductor substrate (wafer) 1 made of a single crystal silicon by a CVD (Chemical Vapor Deposition) method. A Ti film 52 having a film thickness of 20 nm, a Pt film 53 having a film thickness of 175 nm, a PZT film 54 having a film thickness of 250 nm and an IrO₂ film 55 having a film thickness of 175 nm are successively deposited over the silicon oxide film 51 by sputtering. The Ti film 52 is used as a barrier metal for preventing diffusion of Pb in the PZT film 54 and for improving adhesion power of the interface between the Pt film 53 and the silicon oxide film 51. The PZT film 54 is annealed after film formation at 600° C. for 30 minutes in order to obtain desired properties.

Next, as shown in FIG. 2, a photoresist film spin-coated on the IrO₂ film 55 is exposed and developed to form a resist mask (etching-resistant mask layer) 56 patterned into a predetermined shape. While ultraviolet rays are irradiated to the surface of the resist mask 56, heat-treatment is carried out at about 200° C. This heat-treatment promotes the cross-linking reaction of the polymers that constitutes the photoresist film and increases the degree of polymerization. Therefore, the resist mask 56 can be cured sufficiently.

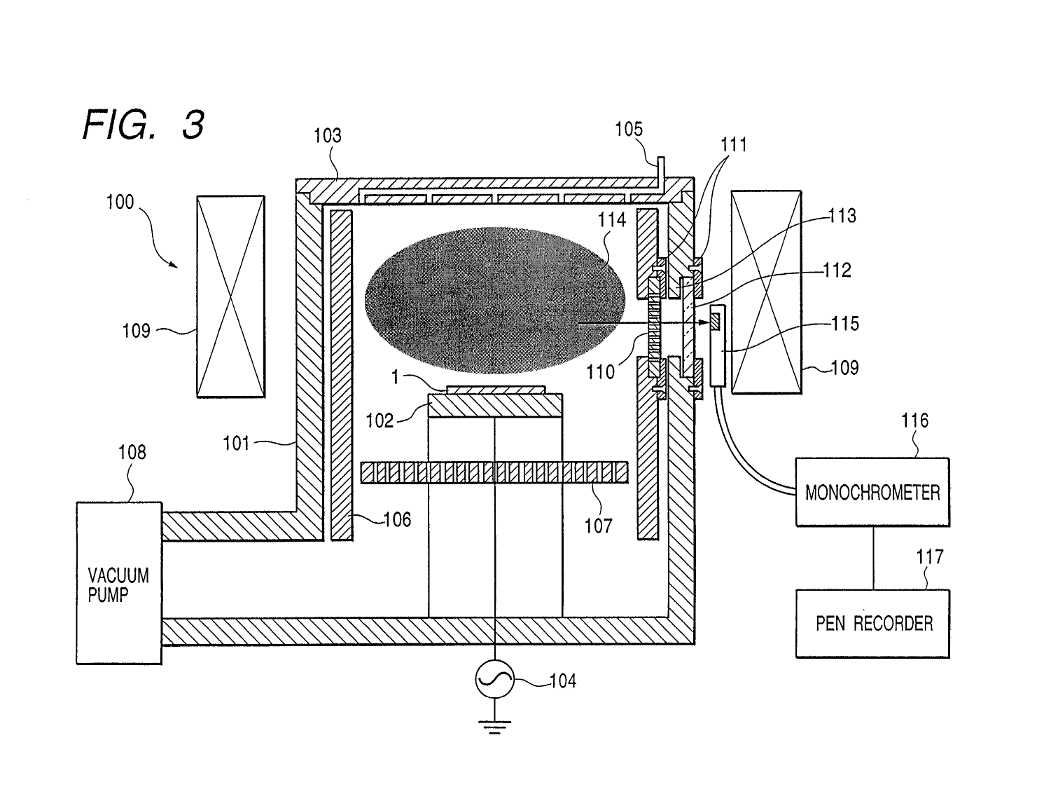

FIG. 3 is a schematic illustration showing the principal portions of a magnetron RIE etcher used for dry etching of the IrO₂ film 55.

Flat sheet-like bottom electrode 102 and top electrode 103 area so disposed to oppose each other inside a chamber 101 that is formed of aluminum and is to serve as a processing unit of the magnetron RIE etcher 100. The bottom electrode 102 that is connected to an RF power source 104 serves as a stage on which a semiconductor substrate (wafer) as a sample is placed. A gas introduction pipe 105 is provided to a part of the top electrode 103, that is connected to the ground potential, in order to supply an etching gas into the chamber 101.

A wall plate 106 is disposed round the bottom electrode 102 so as to prevent reaction products of etching from adhering to the inner wall of the chamber 101. A baffle plate 107 is positioned below the bottom electrode 102. The wall plate 106 can be easily dismounted from the chamber 101 so that the reaction products adhering to the inner wall can be removed periodically. A vacuum pump 108 for decompressing the interior of the chamber 101 to an arbitrary pressure is provided to one of the ends of the chamber 101. A rotary magnet 109 is disposed outside the chamber 101. The magnetic field generated by this rotary magnet 109 and an RF bias applied by the RF power source 104 together create a high density plasma 114 between the top electrode 103 and the bottom electrode 102.

A thin pipe assembly 110 having a thin disc-like shape is fitted to the wall surface of the wall plate 106 round the bottom electrode 102 by fixing means such as a clamp 111. This thin pipe assembly 110 is formed by thinly slicing a bundle of fine quartz glass pipes. Rays of light incident to the surface of the thin pipe assembly 110 mainly transmit through the respective fine glass pipes and reach the back surface. A transparent quartz glass window 112 is fixed by fixing means such as a clamp 111 to the wall of the chamber 101 at the position opposing the thin pipe assembly 110. An O-ring 113 is fitted into a clearance between the quartz glass window 112 and the wall surface of the chamber 101 and keeps the interior of the chamber 101 air-tight.

A plasma monitor unit is disposed outside the quartz glass window 112 in order to monitor light emission of the plasma 114 generated between the bottom electrode 102 and the top electrode 103 during plasma etching, and to judge the end point of etching. The plasma monitor unit comprises a light emission detection monitor 115 for detecting the intensity of emission of the plasma passing through the thin pipe assembly 110 and through the quartz glass window 112, a monochrometer 116 for selecting the rays of light having a desired wavelength from among the plasma emission, and a pen recorder 117 for recording the emission intensity of the plasma.

In this embodiment, the IrO₂ film 55 is etched using an etching gas containing a chlorine (Cl₂) gas as the main component and oxygen (O₂) as an additional gas. The flow rate of the chlorine gas is 40 scm and that of oxygen, 10 scm. The internal pressure of the chamber 101 is set to 5 mTorr, the RF bias, to 1,200 W (13.56 MHz), and the temperature of the stage (bottom electrode 102), to 30° C. For comparison, the IrO₂ film 55 is etched, too, using an etching gas comprising only the chlorine gas (flow rate=50 sccm) without adding oxygen.

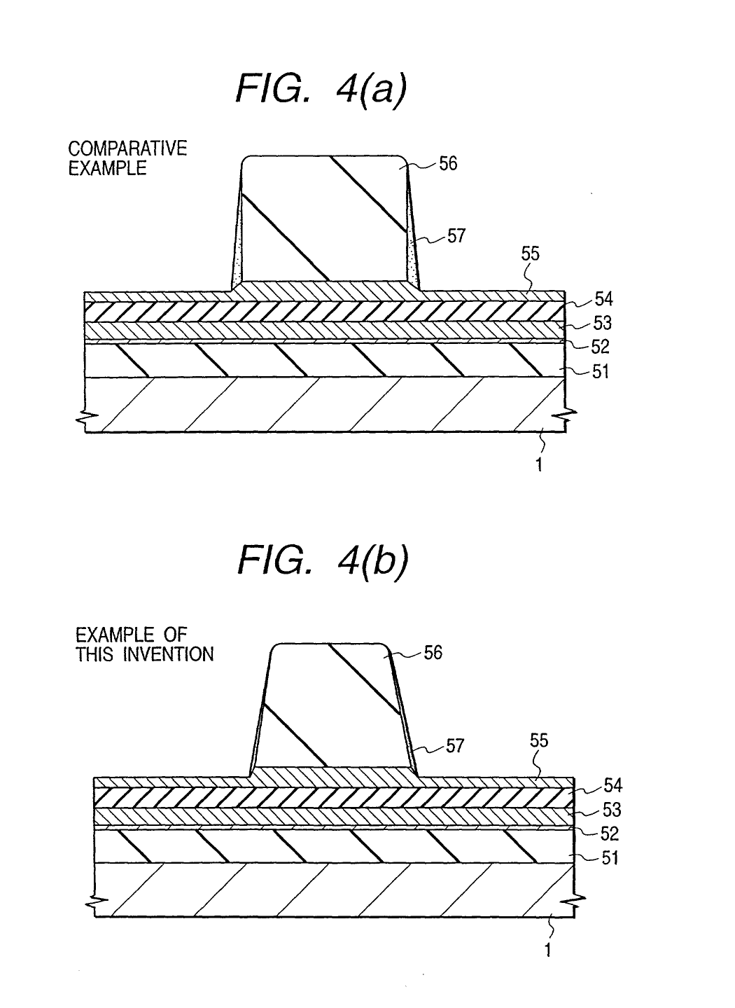

When etching of the IrO₂ film 55 is started, a part of the reaction products formed on the surface of the IrO₂ film 55 and having a low vapor pressure adheres to the resist mask 56 and to the side surface of the IrO₂ film 55 below the former, as shown in FIG. 4(a) in the case where the etching gas not containing oxygen (chlorine gas alone) is used. In this instance, a side wall adhesion film 57 is formed. In contrast, when the etching gas containing oxygen (chlorine+oxygen) is used, the amount of the side wall adhesion film 57 adhering to the resist mask 56 and to the side surface of the IrO₂ film 55 below the resist mask 56 is slight as shown in FIG. 4(b).

Thereafter, etching is continued until the underlying PZT film 54 is exposed (just etching). Etching is completed at the point when the over-etching amount of the PZT film 54 exceeded 50%. The term “just etching” used hereby means etching that is conducted from the start of exposure of the underlying film (PZT film 54) of the film (IrO₂ film 55) as the object film of etching at a part of the wafer to the exposure of the entire surface. The term “over-etching” means additional etching that is started from the end point of etching (end point of just etching) and is directed to completely remove residues of the etching object film remaining at the step portions of the wafer surface, and so forth. The term “over-etching amount” represents a percent fraction of the over-etching time to the etching time of the etching object film.

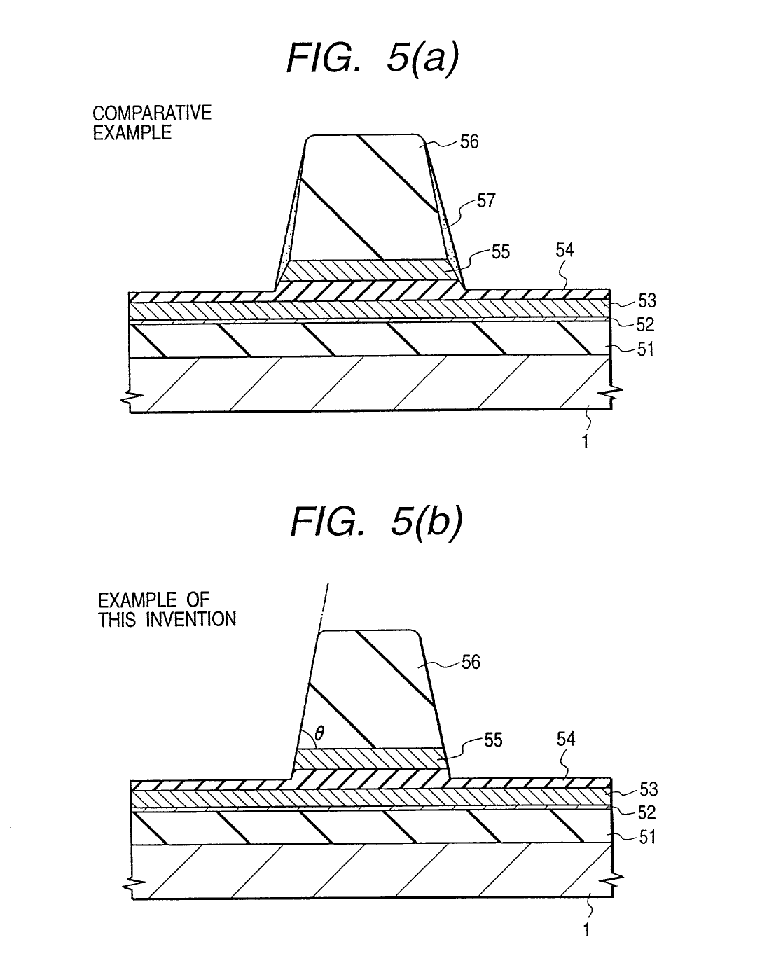

As a result, when the etching gas not containing oxygen is used, large amounts of side wall adhesion film 57 remain on the resist mask 56 and on the side surface of the IrO₂ film 55 below the resist mask 56 as shown in FIG. 5(a). In contrast, when the etching gas containing oxygen is used, the pattern can be obtained in which the side wall adhesion film 57 hardly remains on the side surface of the resist mask 56 and on the IrO₂ film 55 below the resist mask 56 as shown in FIG. 5(b). At this time, the pattern side surface of the IrO₂ film 55 exhibits the taper shape expanding downward, and the angle of inclination (θ) of the slope is around 70°.

Another experiment reveals that when the angle of inclination (θ) of the pattern side surface of the IrO₂ film 55 is below 80°, the adhesion amount of the side wall adhesion film 57 decreases, and particularly when the angle of inclination is below 75°, a pattern can be obtained in which the side wall adhesion film 57 hardly adheres. When an etching gas containing an inert gas such as an Ar gas together with oxygen (chlorine+oxygen+inert gas) is used, too, substantially the same result can be obtained as when the etching gas described above (chlorine+oxygen) is used. When etching (just etching) of the IrO₂ film 55 is conducted by using the etching gas not containing oxygen (chlorine gas alone, or chlorine gas and an inert gas such as the Ar gas) and then by over-etching the underlying PZT film 54 using the etching gas containing oxygen, too, a pattern can be obtained in which the side wall adhesion film 57 does not adhere to the side surface.

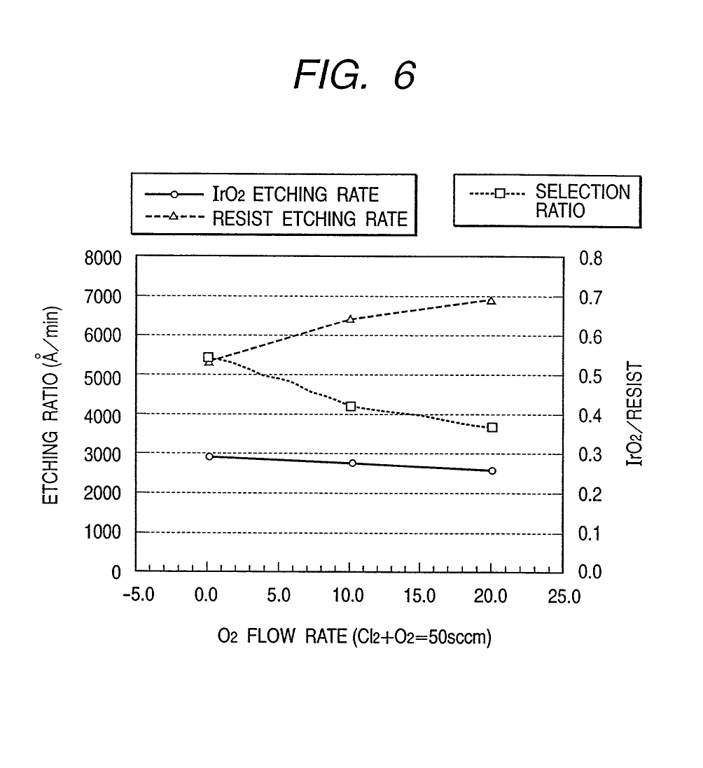

FIG. 6 is a graph showing oxygen flow rate dependence of the etching characteristics when the total flow rate of the etching gas is 50 sccm. As shown in the graph, the etching rate of the resist mask increases with the increase of the flow rate of oxygen added to the etching gas, and selection ratio of the IrO₂ film to the resist drops. This reveals that when the etching gas comprising the chlorine gas as the main component and containing oxygen as the additional gas is used, the oxygen radicals generated in the plasma promote etching of the resist mask, and that the pattern devoid of the side wall adhesion film can be obtained as the side wall is cut and recessed. Therefore, the additional gas is not particularly limited to oxygen. In other words, substantially the same effect can be obtained as oxygen by adding those gases which generate the oxygen radicals in the plasma as typified by ozone, or which lower the selection ratio of the IrO₂ film to the resist.

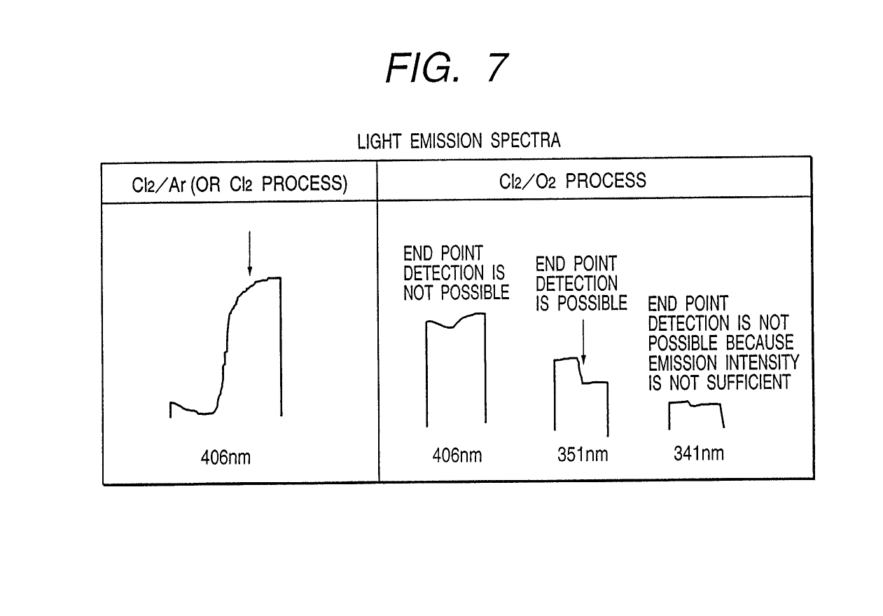

FIG. 7 is a graph showing data of light emission spectra during etching of the IrO₂ film. As shown in this graph, when etching is conducted using the chlorine gas alone or the etching gas containing the inert gas such as Ar in addition to the chlorine gas, light emission (wavelength: 406 nm) from Ti contained in PZT increases when etching of the IrO₂ film is completed and the underlying PZT film is exposed. Therefore, the end point of etching is judged by monitoring this light emission, and etching is stopped (or over-etching is started) on the basis of this judgement. In contrast, when the gas containing oxygen in addition to the chlorine gas is used, light emission (wavelength: 406 nm) from Ti can not be detected because the composition of the plasma changes. In this case, therefore, light emission (wavelength: 351 nm) from Ir contained in IrO₂ is monitored, and the end point of etching is set to the point at which etching of the IrO₂ film is completed and the underlying PZT film is exposed, that is, the point at which light emission from Ir decreases. Etching is stopped (or over-etching is started) on the basis of this judgement.

In still another experiment, a 175 nm-thick Pt (platinum) film deposited on the PZT film and a 175 nm-thick IrO₂ film deposited similarly on the PZT film are respectively etched using the etching gas containing oxygen in addition to the chlorine gas. When over-etching of the Pt film is done to a ratio of 15%, etching is stopped. When over-etching of the IrO₂ film is done to a ratio of 72%, etching is stopped. As a result, it is found that a substantial difference of the cut amount of the underlying PZT film does not occur between them.

It is thus found that when the IrO₂ film is etched using the etching gas containing oxygen in addition to the chlorine gas, the over-etching time for removing the reaction products adhering to the pattern side wall increases, but the cut amount per unit time decreases because the etching rate of the underlying PZT film drops, too.

Embodiment 2:

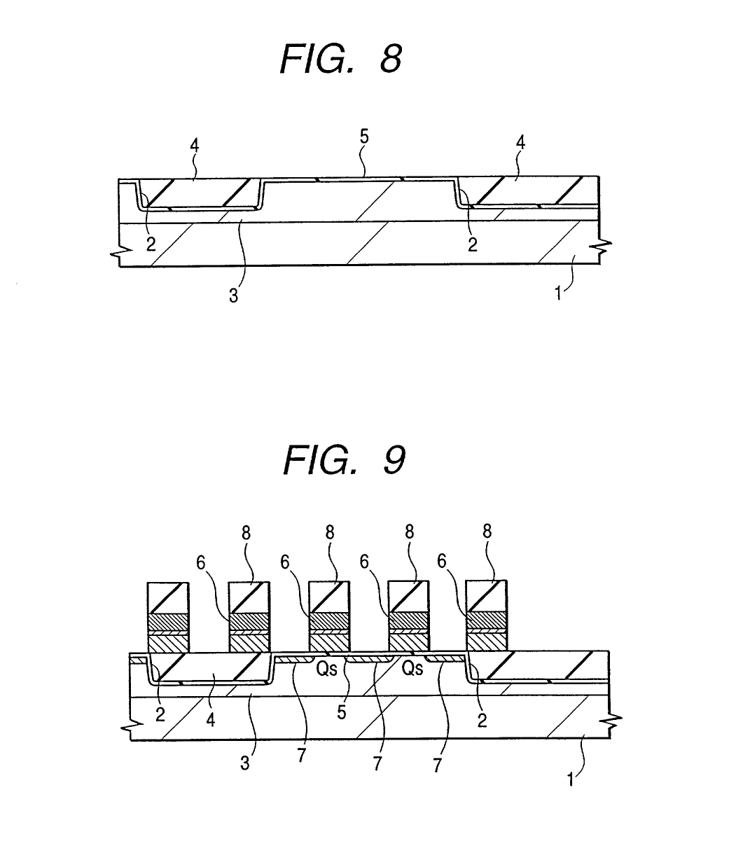

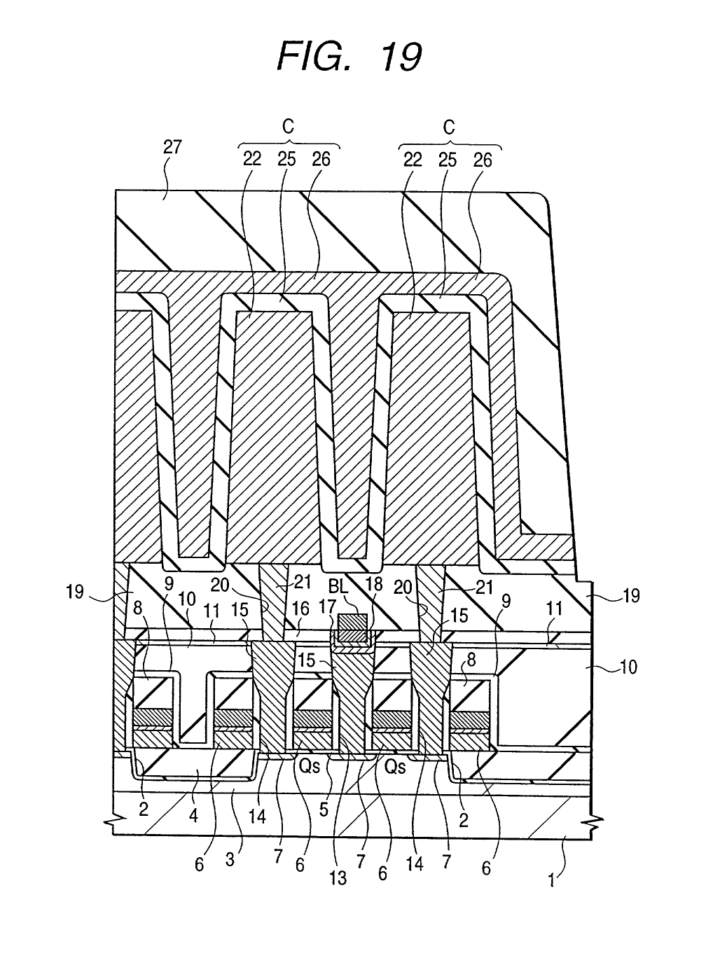

Another embodiment of the present invention applied to a method of fabricating a DRAM as one of the semiconductor memories will be explained with reference to FIGS. 8 to 19.

To fabricate this DRAM, device isolation trenches 2 and p type wells 3 are first formed on a main plane of a semiconductor substrate (wafer) 1 having p type conductivity and a specific resistance of about 10 Ωcm, for example, as shown in FIG. 8. The device isolation trench 2 is formed by first dry etching the semiconductor substrate 1 to form a trench, depositing then a silicon oxide film 4 by a CVD process over the semiconductor substrate 1 inclusive of the interior of the trench, and polishing the silicon oxide film 4 by CMP (Chemical Mechanical Polishing) in such a manner as to leave it only inside the trench. The p type well 3 is formed by implanting an n type impurity such as P (phosphorus) into the semiconductor substrate 1 and then annealing the semiconductor substrate 1 to thermally diffuse the impurity.

After the surface of the p type well 3 is washed with a HF (hydrofluoric acid)-based washing solution, the semiconductor substrate 1 is wet oxidized to form a clean gate oxide film 5 on the surface of the p type well 3.

Next, gate electrodes 6 (word lines) are formed over the gate oxide films 5 as shown in FIG. 9. Subsequently, n type semiconductor regions 7 (source-drain) are formed in the p type wells on both sides of the gate electrode 6. Thus, the memory selection MISFET Qs are formed.

The gate electrode 6 is formed, for example, by depositing by CVD a polycrystalline silicon film doped with an n type impurity such as P (phosphorus) on the semiconductor substrate 1, forming then a WN (tungsten nitride) film and a W (tungsten) film by sputtering, and further depositing a silicon nitride film 8 by CVD. These films are then patterned with the photoresist film as the mask. The n type semiconductor region 7 (source and drain) is formed by ion implanting an n type impurity such as P (phosphorus) into the p type well 3.

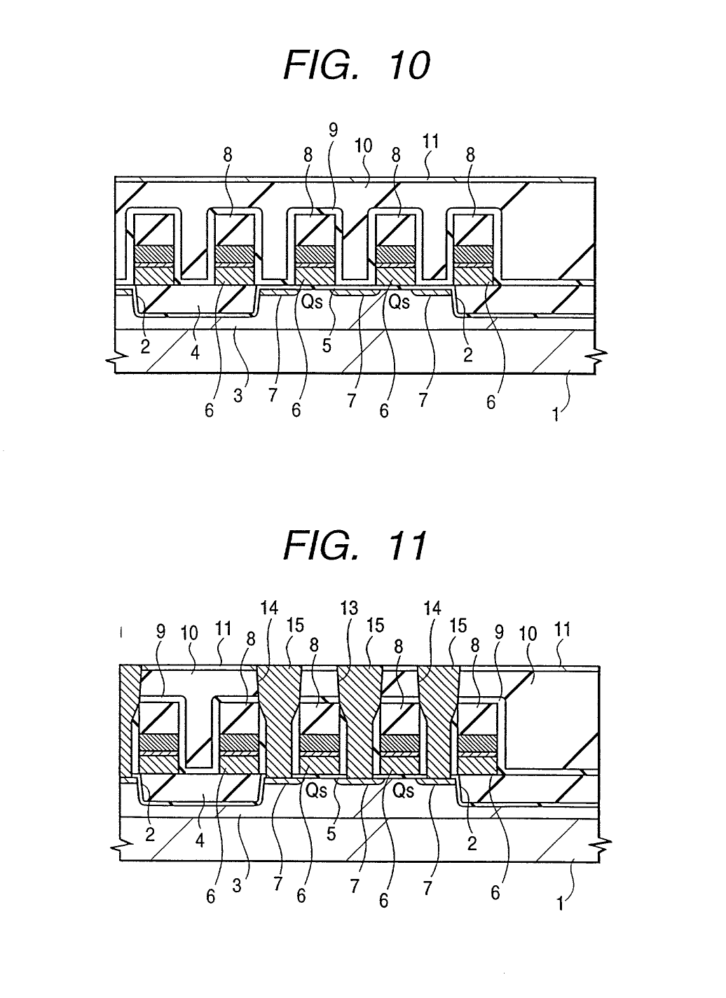

Next, a silicon nitride film 9 and a silicon oxide film 10 are deposited by CVD over the semiconductor substrate 1 as shown in FIG. 10. The silicon oxide film 10 is then polished by CMP so as to render its surface flat and smooth. A silicon oxide film 11 is then deposited on the silicon oxide film 10 by CVD. This silicon oxide film 11 is formed in order to protect the surface of the silicon oxide film 10 that is finely scratched by polishing by CMP.

Contact holes 13 and 14 are formed by dry etching the silicon oxide films 11 and 10 and the silicon nitride film 9 over the n type semiconductor region 7 (source and drain) with the photoresist as the mask as shown in FIG. 11. A plug 15 made of a polycrystalline silicon film is formed inside each contact hole 13, 14. The plug 15 is formed, for example, by depositing by CVD a polysilicon film doped with an n type impurity such as P (phosphorus) over the silicon oxide film 11, inclusive of the interior of the contact holes 13 and 14, and then removing the polysilicon film on the silicon oxide film 11 by CMP (or by etch-back) in such a fashion as to leave the polysilicon film only inside the contact holes 13 and 14.

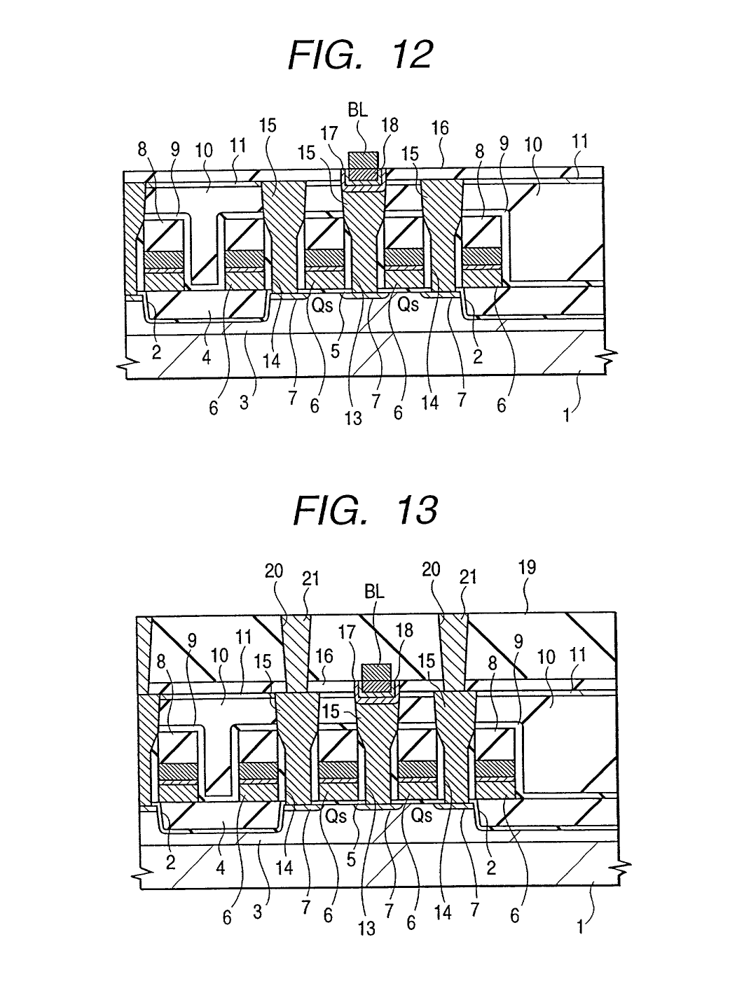

Next, as shown in FIG. 12, a silicon oxide film 16 is deposited by CVD over the silicon oxide film 11, and is subsequently dry etched to form each through-hole 17 on the contact hole 13. After a plug 18 is formed inside each through-hole 17, a bit line BL is formed on the plug 18.

The plug 18 is formed by, for example, the steps of depositing a Ti film, a TiN film and a W film by CVD or sputtering, over the silicon oxide film 16 inclusive of the interior of the through-hole 17, and removing these films over the silicon oxide film 16 by CMP. The bit line BL is formed by, for example, depositing a W film over the silicon oxide film 16 by sputtering, and then patterning the W film by dry etching with the photoresist film as the mask.

Next, as shown in FIG. 13, a silicon oxide film 19 is deposited by CVD over the silicon oxide film 16. Subsequently, through-holes 20 are formed over the contact holes 14 by dry etching the silicon oxide film 19. A plug 21 is formed inside each through-hole 20. The plug 21 is formed, for example, by depositing by CVD a polysilicon film doped with an n type impurity such as P (phosphorus) on the silicon oxide film 19 inclusive of the interior of the through-hole 20, and polishing by CMP (or by etch-back) the polysilicon film over the silicon oxide film 19 in such a fashion as to leave the polysilicon film only inside the through-hole 20.

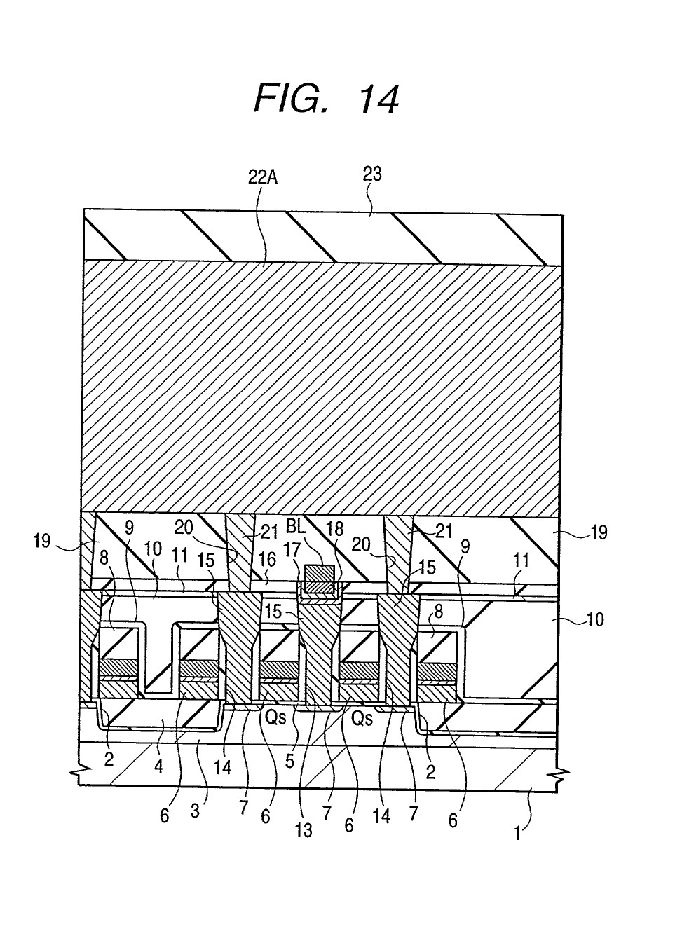

Next, as shown in FIG. 14, an IrO₂ film 22A is deposited by sputtering over the silicon oxide film 19 and then a silicon oxide film 23 is deposited over the IrO₂ film 22A by CVD. It is necessary to deposit the IrO₂ film 22A to a large thickness (for example, about 1 μm) in order to increase the storage charge amount by increasing the surface area of the lower electrode 22 of the information storage capacitance device C that is to be formed in the later-appearing process step.

Incidentally, an oxidation-resistant barrier layer (for example, a silicon nitride film) may be formed between the silicon oxide film 19 and the IrO₂ film 22A in order to prevent the plug 21 inside the through-hole 20 from being oxidized and from increasing its resistance when a PZT film 25A, that is to be deposited over the IrO₂ film 22A in a subsequent process step, is annealed. However, since the IrO₂ film 22A has a high oxygen barrier property, the oxidation-resistant barrier layer need not be formed separately if this material is used as the bottom electrode material. On the other hand, when Pt, or the like, is used as the bottom electrode material, such an oxidation-resistant barrier layer is formed preferably.

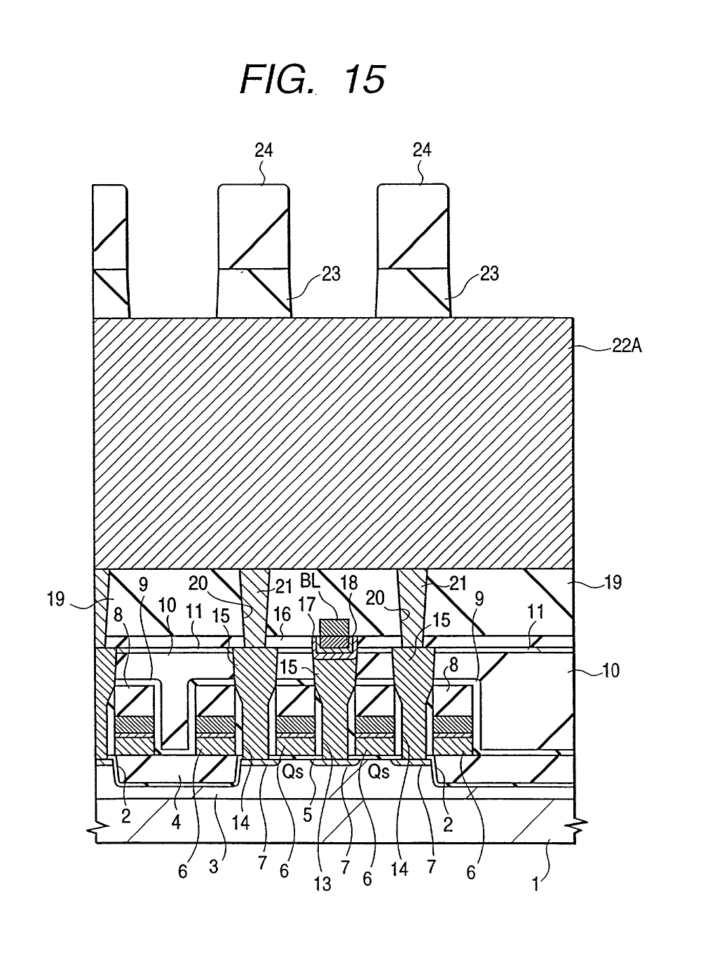

Next, as shown in FIG. 15, the photoresist film formed over the silicon oxide film 23 is patterned to form a resist mask 24, and the silicon oxide film 23 is dry etched using this resist mask 24.

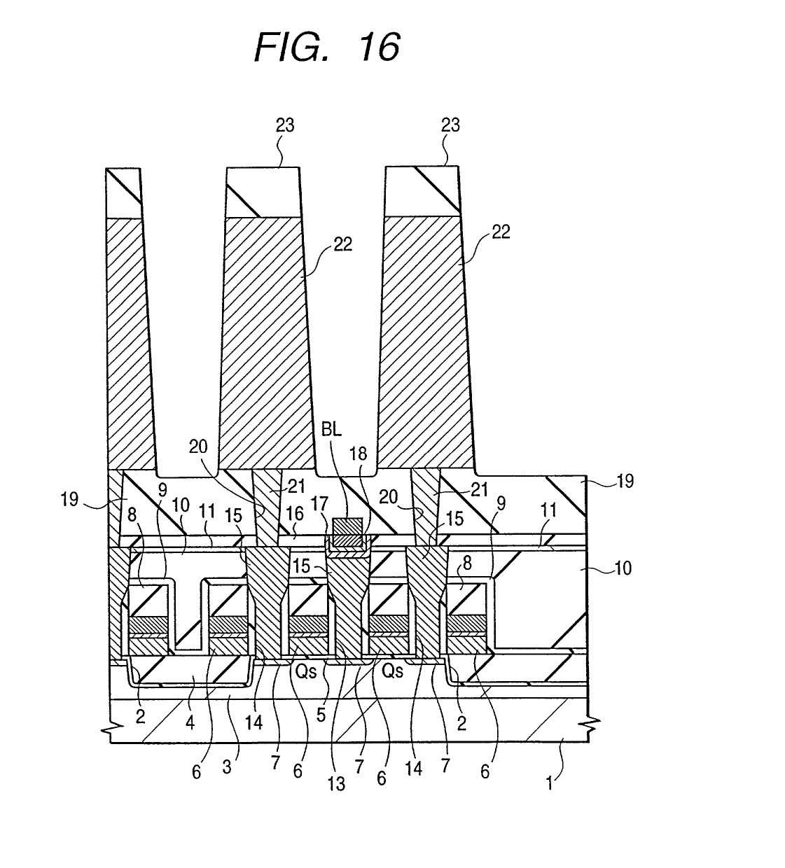

After the resist mask 24 is removed by ashing, the IrO₂ film 22A is dry etched with the silicon oxide film 23 as the mask as shown in FIG. 16, forming the bottom electrode 22 of the information storage capacitance device C having a substantially circular cylindrical pattern. The ratio of the height to the diameter of the bottom electrode 22 (aspect ratio) is about 3.5, for example.

When the etching method of Embodiment, that uses the etching gas comprising the chlorine gas as the main component and containing oxygen as the additional gas, is used at this time, a pattern can be obtained in which a side wall adhesion film hardly adheres to the resist mask 24 and to the side surface of the IrO₂ film 22A (bottom electrode 22) below the mask 24. In consequence, pattern accuracy of the bottom electrode 22 can be improved. Furthermore, because over-etching for removing the side wall adhesion film and subsequent washing become unnecessary, the cut amount of the underlying silicon oxide film 23 can be reduced.

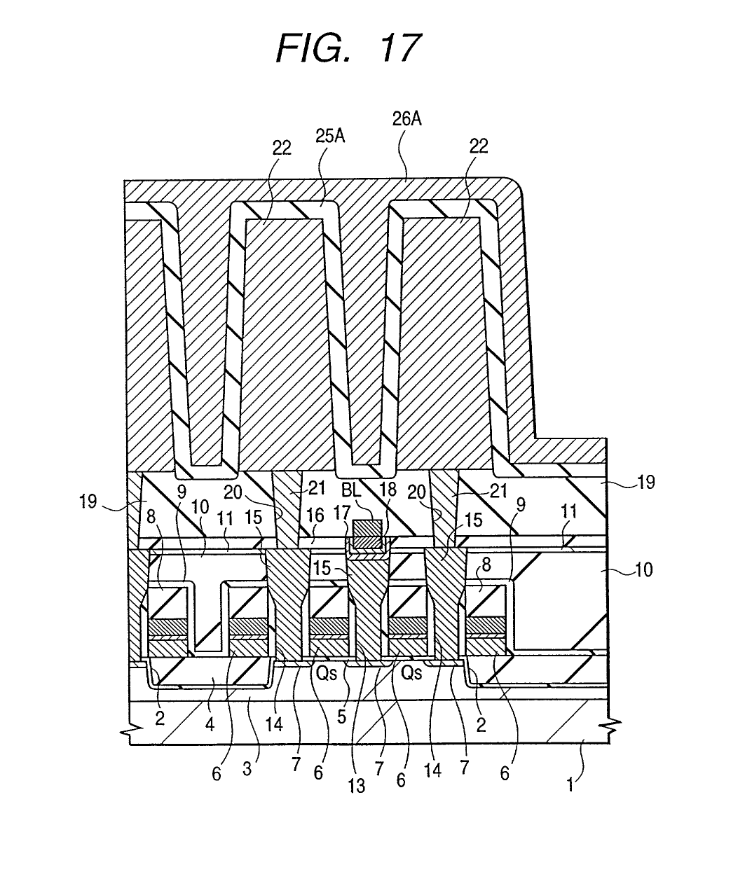

Next, a PZT film 25A and an IrO₂ film 26A are deposited by sputtering over the bottom electrode 22 as shown in FIG. 17. After the film formation, the PZT film 25A is annealed at 600° C. for about 30 minutes, for example, so as to obtain desired performance.

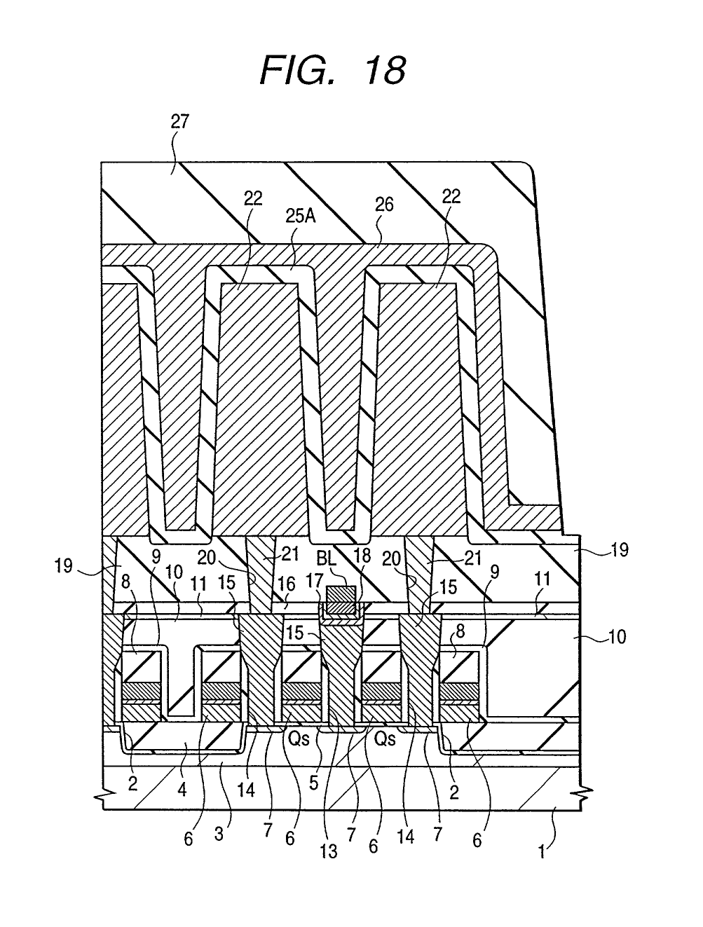

A patterned resist mask 27 is then formed over the IrO₂ film 26A as shown in FIG. 18, and the IrO₂ film 26A is dry etched with this resist mask 27, forming the top electrode 26 of the information storage capacitance device C. The etching method of Embodiment 1, that uses the etching gas comprising the chlorine gas as the main component and containing oxygen as the additional gas, is used this time, and a pattern can be obtained in which the side wall adhesion film does not adhere to the photoresist film 27 and to the side surface of the IrO₂ film 26A (top electrode 26) below the former. In consequence, pattern accuracy of the top electrode 26 can be improved.

Thereafter, the PZT film 25A is dry etched using the resist mask 27 (or a resist mask formed afresh separately), forming a capacitance insulation film 26 of the information storage capacitance device C. By the process steps described so far, the information storage capacitance device C having the bottom electrode 22 comprising the IrO₂ film 22A, the capacitance insulation film 25 comprising the PZT film 25 and the top electrode 26 comprising the IrO₂ film 26A is constituted. In this way, the memory cell of the DRAM comprising the memory cell selection MISFET Qs and the information storage capacitance device C connected in series with the former is completed. Incidentally, wiring of about two layers is further formed over the information storage capacitance device C in the actual DRAM process, but the explanation will be hereby omitted.

Embodiment 3:

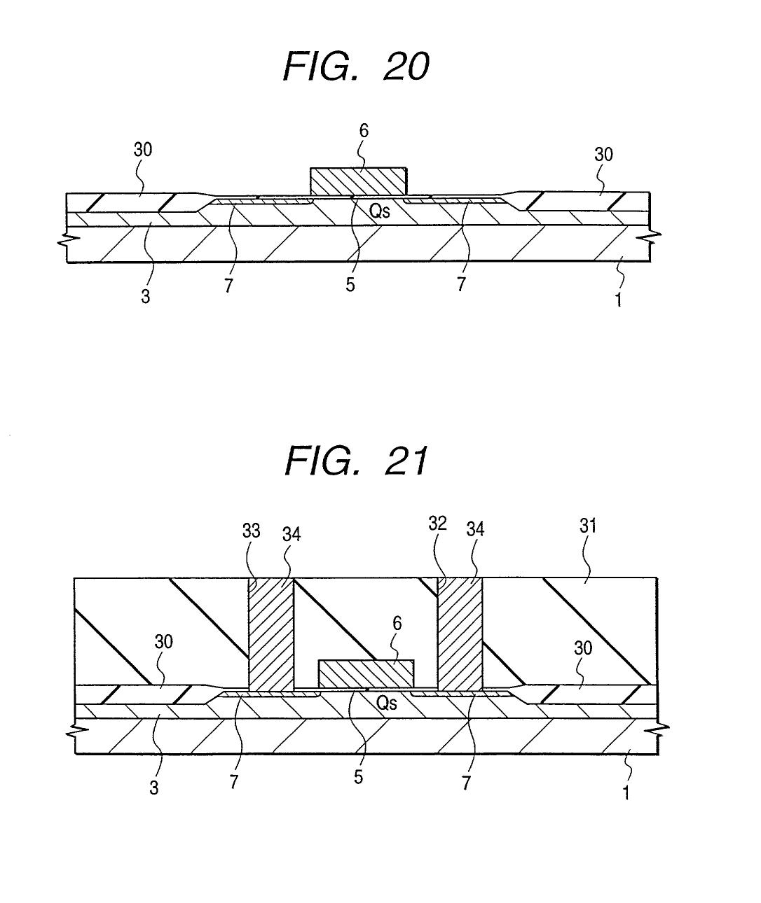

Still another embodiment wherein the present invention is applied to a fabrication method of FeRAM (ferroelectric memory) as one of the semiconductor memories will be explained with reference to FIGS. 20 to 26. Incidentally, this FeRAM comprises one memory cell selection MISFET and one information storage capacitance device C in the same way as the DRAM described above.

Initially, a field oxide film 30 for device isolation and a p type well 3 are formed on a main plane of a semiconductor substrate (wafer) 1 made of single crystal silicon having a p type conductivity and resistivity of about 10 Ωcm as shown in FIG. 20. A field oxide film 30 is formed by a known LOCOS process. The p type well 3 is formed by ion-implanting n type impurity ions such as P (phosphorus) and then annealing the semiconductor substrate 1 to thermally diffuse the impurity.

After the surface of the p type well 3 is washed with an HF (hydrofluoric acid)-based washing solution, the semiconductor substrate 1 is wet oxidized to form a clean gate oxide film 5 is formed on the p type well 3. After a gate electrode 6 is formed subsequently over the gate oxide film 5, an n type impurity such as P (phosphorus) is ion-implanted to form an n type semiconductor region 7 (source and drain).

Next, a silicon oxide film 10 is formed by CVD a over the semiconductor substrate 1 as shown in FIG. 21. Subsequently, a silicon oxide film 31 is polished to a flat and smooth surface by CMP. The silicon oxide film 31 over the n type semiconductor region 7 (source and drain) is dry etched with a photoresist film as a mask, forming contact holes 32 and 33. A plug 34 is formed inside each contact hole 32, 33. The plug 34 is formed, for example, by depositing a W (tungsten) film by CVD over the silicon oxide film 31, inclusive of the interior of the contact holes 32 and 33, and then removing the W film on the silicon oxide film 31 by CMP (or by etch-back) in such a fashion as to leave the W film only inside contact holes 32 and 33.

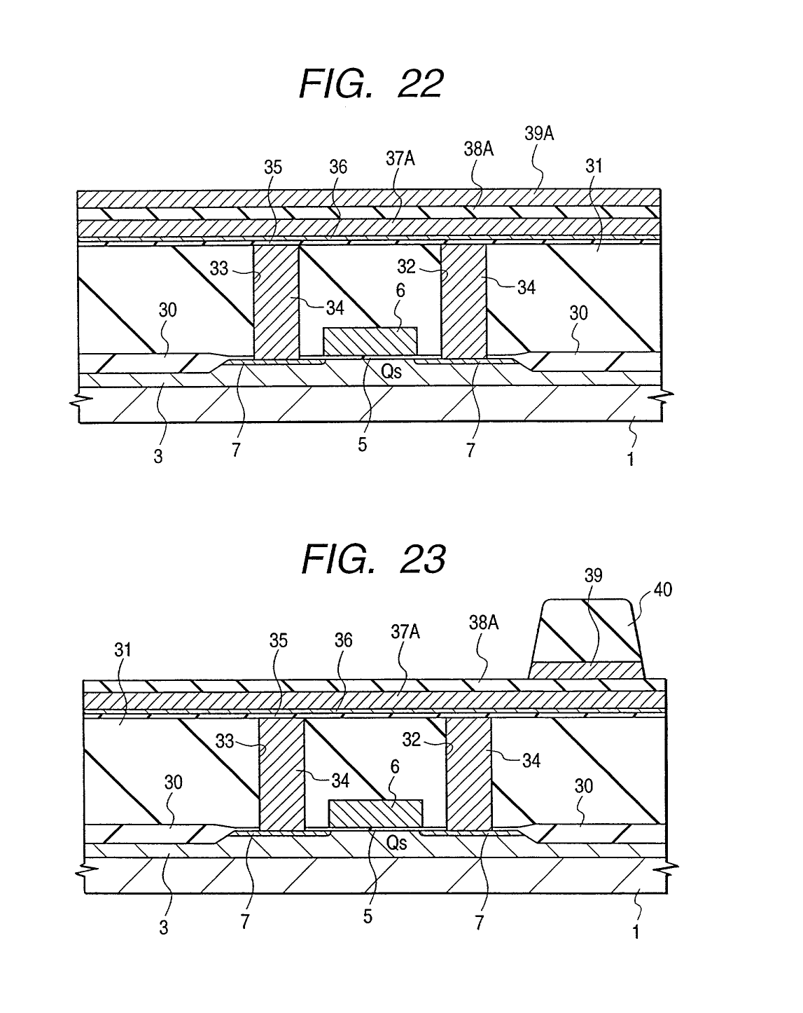

Next, a silicon nitride film 35 is deposited by CVD over the silicon oxide film 31 as shown in FIG. 22. An about 20 nm-thick TiN film 36, an about 175 nm-thick Pt film 37A, an about 250 nm-thick PZT film 38A and an about 175 nm-thick IrO₂ film 39A are then deposited serially by sputtering over the silicon nitride film 35. The PZT film 38A is annealed at 600° C. for about 30 minutes, for example, after the film formation in order to obtain desired performance.

Here, the silicon nitride film 35 is used as an oxidation-resistant barrier layer to prevent the plugs 34 inside the contact holes 32 and 33 made of the W film from being oxidized and increasing its thickness during annealing of the PZT film 38A. The TiN film 36 is used as a barrier metal for preventing diffusion of Pb in the PZT film 38A and for improving adhesion power of the interface between the Pt film 37A and the silicon nitride film 35.

This embodiment uses the Pt film 37A as a conductor film for the bottom electrode, but is not particularly limited thereto. For example, it is possible to use a single-layered film consisting of a platinum group metal as a main constituent element, or its oxide or its complex oxide, such as Ir, IrO₂, Ru (ruthenium), RuO₂, etc, or a laminated conductor film consisting of two or more of these members. Depending on the material of these conductor films for the bottom electrode, the barrier metal of the TiN film 36 can be omitted. Besides the silicon nitride film 35 described above, it is also possible to use the Ir film, for example, as the oxidation-resistant barrier layer.

Though this embodiment uses the PZT film 38A as the ferroelectric film for the capacitance insulation film, the invention is not particularly limited thereto. The ferroelectric film may be those which comprise high dielectric or ferroelectric materials as the main component and have a perovskite structure or a structure equivalent to the former, such as BST, PLT, PLZT, SBT, and so forth. The film formation method of these high dielectric and ferroelectric films is not particularly limited to sputtering, and a sol-gel process may be used, for example.

It is further possible to use an Ir film, that has a high degradation prevention effect of PZT in the same way as the IrO₂ film, for the conductor film for the top electrode, or a laminate film of the IrO₂ film and the Ir film.

Next, the photoresist film formed on the IrO₂ film 39A is patterned to form a resist mask 40 as shown in FIG. 23. The IrO₂ film 39A is dry etched with this resist mask 40 as the mask, forming the top electrode 39 of the information storage capacitance device C. The etching method of Embodiment 1, that uses the etching gas comprising the chlorine gas as the main component and containing oxygen as the additional gas, is used at this time, and a pattern can be obtained in which the side wall adhesion film hardly adheres to the resist mask 40 and to the side surface of the IrO₂ film 39A (top electrode). In consequence, pattern accuracy of the top electrode 39 can be improved, and over-etching and washing for removing the side wall adhesion film become unnecessary.

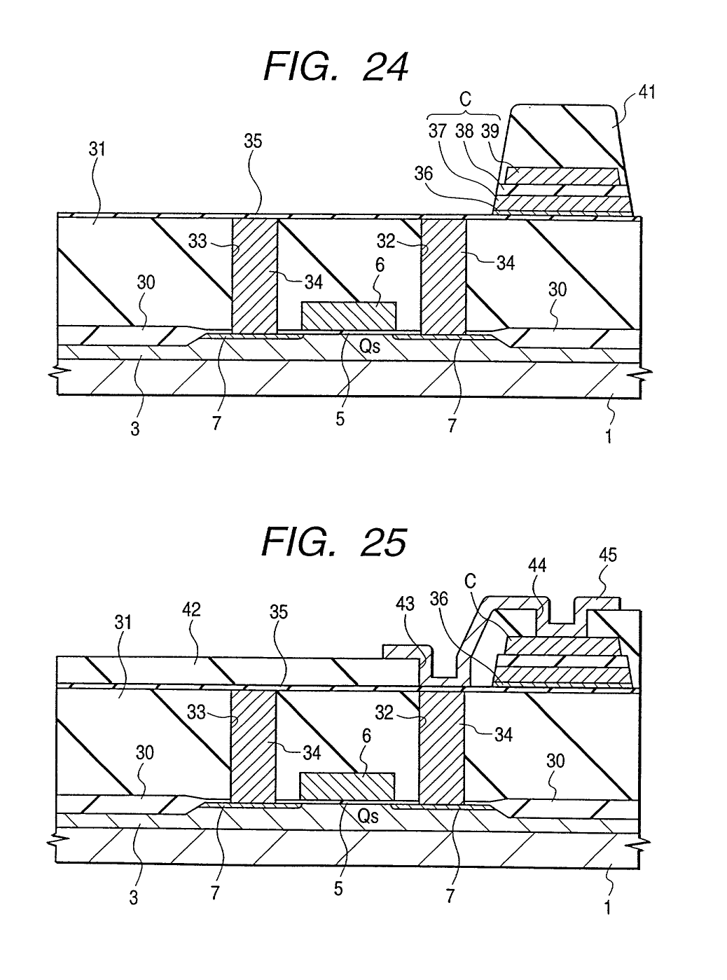

Next, after the resist mask 40 is removed by ashing, the photoresist film formed on the top electrode 39 is patterned to form a resist mask 41 as shown in FIG. 24. The PZT film 38A, the Pt film 37A and the TiN film 36 are dry etched with this resist mask 41 as the mask. The process steps described so far provides the information storage capacitance device C having the bottom electrode 37 comprising the Pt film 37A, the capacitance insulation film 38 comprising the PZT film 38A and the top electrode 39 comprising the IrO₂ film 39A. In this way, the FeRAM comprising the memory cell selection MISFETQs and the information storage capacitance device C connected in series with the MISFETQs is completed.

By employing the etching method of Embodiment 1 using the etching gas, that comprises the chlorine gas as the main component and contains oxygen as the additional gas at this time, the pattern can be obtained in which the side wall adhesion film hardly adheres to the resist mask 41 and to the side surfaces of the PZT film 38A (capacitance insulation film 38) and the Pt film 37A (bottom electrode 37) below the resist mask 41. In consequence, pattern accuracy of the capacitance insulation film 38 and the lower electrode 37 can be improved, and over-etching and washing for removing the side wall adhesion film become unnecessary.

Incidentally, the PZT film 38A and the Pt film 37A may be etched individually by using different resist masks. Alternatively, the IrO₂ film 39A, the PZT film 38A and the Pt film 37A may be etched successively by using the resist mask 40 that is used for etching of the IrO₂ film 39A (top electrode 39).

In comparison with etching of the IrO₂ film 39A, the amount of the side wall adhesion film adhering to the side surface of the pattern is smaller in etching of the PZT film 38A and the Pt film 37A. Therefore, when these films are etched using the etching gas containing oxygen, the selection ratio to the resist drops excessively. In consequence, the cut amount of the resist mask increases and pattern accuracy is likely to drop in some cases. In such cases, it is advisable to first use an etching gas not containing oxygen (chlorine gas alone, or the gas containing an inert gas such as Ar added to the chlorine gas) for etching the PZT film 38A and the Pt film 37A, and then to use an etching gas containing additional oxygen for over-etching the underlying film and for removing the adhesion film of the pattern side wall.

Next, after the resist mask 41 is removed by ashing, the silicon oxide film 42 deposited by CVD over the information storage capacitance device C and the silicon nitride film 35 below the silicon oxide film 42 are etched, thereby forming through-holes 43 on the contact holes 32 and through-holes 44 over the information storage capacitance device C, as shown in FIG. 25. Wiring 45 is successively formed over the silicon oxide film 42. The information storage capacitance device C and the memory cell selection MISFETQs are then connected electrically through the wiring 45 and the plug 34 inside the contact hole 32. This wiring 45 is formed by depositing a TiN film by sputtering on the silicon oxide film 42 inclusive of the interior of the through-holes 43 and 44 and patterning this TiN film by dry etching with the photoresist film as the mask.

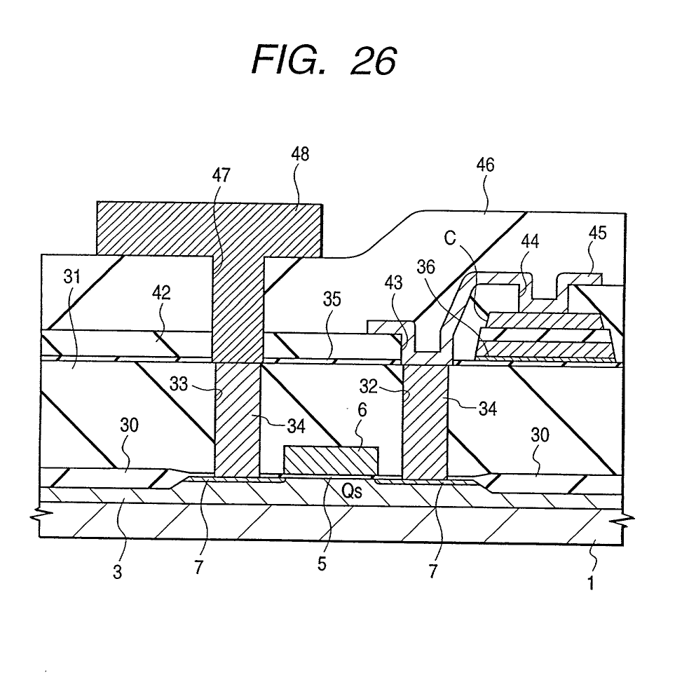

Next, as shown in FIG. 26, the silicon oxide film 46 that is deposited by CVD over the wiring 45 is etched, forming the through-hole 47 over the contact hole 33. A bit line 48 is formed over the silicon oxide film 46, and is connected electrically to the memory cell selection MISFETQs through the plug 34 inside the contact hole 33. The bit line 48 is formed, for example, by first depositing an Al (aluminum) film by sputtering on the silicon oxide film 46 inclusive of the interior of the through-hole 47 and then patterning this Al film by dry etching with the photoresist film as the mask. The process steps described so far complete substantially the FeRAM of this embodiment.

Although the present invention has thus been described concretely in conjunction with several embodiments thereof, the invention is not particularly limited to these embodiments but can be naturally changed or modified in various ways without departing from the scope thereof.

The etching method of the present invention is not particularly limited to etching using the etcher of the magnetron RIE system, but can be applied to etching that uses plasma etchers of various systems such as ECR, so-called “Helicon”, ICP, and so forth.

The etching method of the present invention can also be applied to etching that uses a hard mask (inorganic mask) such as a silicon oxide film or a metal film, though the number of steps increases in comparison with etching that uses the resist mask.

Typical effects brought forth by the representative inventions described herein may be summarized as follows.

The fabrication method according to the present invention can reliably prevent the reaction products having a low vapor pressure from adhering to the side surface of the pattern when the Ir-based conductor film deposited over the semiconductor substrate is dry etched. Therefore, the present invention can improve the production yield and reliability of the semiconductor integrated circuit devices (such as DRAMs and FeRAMs) using the Ir-based conductor film for the electrode material. Because the present invention can process a miniature pattern comprising the Ir-based conductor film with high dimensional accuracy, the present invention can further promote scale-down and high integration density of semiconductor integrated circuit devices (such as DRAMs and FeRAMs) using the Ir-based conductor film for the electrode material.

1. A method of fabricating a semiconductor integrated circuit device comprising the step of:
applying a dry etching treatment to a first film formed of Ir or IrO₂ as a main constituent element over a first major surface of a semiconductor wafer having a photoresist film formed and patterned thereon, in a gas atmosphere containing a chlorine gas as a main component of an etching gas and oxygen as an additional gas.

2. A method of fabricating a semiconductor integrated circuit device according to claim 1, wherein said first film is a film formed of IrO₂ as a main constituent element.

3. A method of fabricating a semiconductor integrated circuit device according to claim 2, further comprising the step of:
removing a side wall adhesion film adhering to a side wall of a pattern during said dry etching treatment, during said dry etching treatment or during a gaseous phase process subsequent to said dry etching treatment.

4. A method of fabricating a semiconductor integrated circuit device comprising the steps of:
(a) applying a dry etching treatment to a first film formed of Ir or IrO₂ as a main constituent element, over a first major surface of a semiconductor wafer having an etching-resistant mask layer formed and patterned thereon, in a gas atmosphere containing a chlorine gas as a main component of an etching gas; and
(b) monitoring light emission from Ir during said step (a), judging an end point of etching and stopping etching on the basis of said judgement.

5. A method of fabricating a semiconductor integrated circuit device according to claim 4, wherein an underlying film of said first film is a dielectric film comprising a high dielectric or ferroelectric material having a perovskite structure or a structure equivalent to said perovskite structure.

6. A method of fabricating a semiconductor integrated device according to claim 5, wherein said ferroelectric film comprises BST, PZT, PLT, PLZT or SBT as a main component.

7. A method of fabricating a semiconductor integrated circuit device according to claim 6, wherein said etching-resistant mask layer is a photoresist film.

8. A method of fabricating a semiconductor integrated circuit device according to claim 7, wherein the wavelength of light emission monitored is 351 nm.

9. A method of fabricating a semiconductor integrated circuit device comprising the steps of:
(a) applying a dry etching treatment to a first film formed of a platinum group metal or an oxide thereof as a main constituent element over a first major surface of a semiconductor wafer having a photoresist film formed and patterned thereon, in a gas atmosphere containing a chlorine gas as a main component of an etching gas and oxygen as an additional gas; and
(b) applying an over-etching treatment to said first film by removing a side wall adhesion film adhering during said first etching treatment while an underlying second film having a different material from that of said first film is being etched beyond said first film.

10. A method of fabricating a semiconductor integrated circuit device according to claim 9, wherein the amount of said over-etching is at least 50%.

11. A method of fabricating a semiconductor integrated circuit device according to claim 10, wherein the gas atmosphere during said over-etching contains a chlorine gas as a main component of the etching gas and oxygen as an additional gas.

12. A method of fabricating a semiconductor integrated circuit device according to claim 11, wherein said first film is a film formed of Pt, Ru, RuO₂, Ir or IrO₂ as a main constituent element.

13. A method of fabricating a semiconductor integrated circuit device according to claim 12, wherein the gas atmosphere during said over-etching is substantially the same as the gas atmosphere of said step (a) of applying said dry etching treatment.

14. A method of fabricating a semiconductor integrated circuit device comprising the step of:
applying a dry etching treatment to a first film containing those components which are likely to invite side wall adhesion at the time of etching, over a first major surface of a semiconductor wafer having a photoresist film formed and patterned thereon, in a gas atmosphere containing a chlorine gas as a main component of an etching gas and a gas having a function of lowering a selection ratio to a resist, as an additional gas.

15. A method of fabricating a semiconductor integrated circuit device according to claim 14, wherein said first film is a film formed of a platinum group metal, or a platinum group metal oxide or a complex oxide thereof, or a perovskite type compound or a high dielectric or ferroelectric material having a structure equivalent to said perovskite structure.

16. A method of fabricating a semiconductor integrated circuit device according to claim 15, wherein said gas having a function of lowering a selection ratio to the resist is oxygen.

17. A method of fabricating a semiconductor integrated circuit device according to claim 16, wherein said gas atmosphere further contains an inert gas.

18. A method of fabricating a semiconductor integrated circuit device comprising the steps of:
(a) applying a dry etching treatment to a first film containing those components which are likely to invite side wall adhesion during etching, over a first major surface of a semiconductor wafer having a photoresist film formed and patterned thereon, in a gas atmosphere containing a chlorine gas as a main component of an etching gas and a gas having a function of lowering a selection ratio to a resist as an additional gas; and
(b) applying an over-etching treatment to said first film by removing a side wall adhesion film adhering during said etching process of said first film while an underlying second film made of a different material from that of said first film is being etched beyond said first film.

19. A method of fabricating a semiconductor integrated circuit device according to claim 18, wherein the amount of said over-etching is at least 50%.

20. A method of fabricating a semiconductor integrated circuit device according to claim 19, wherein said gas atmosphere at the time of said over-etching contains a chorine gas as a main component and oxygen as an additional gas.

21. A method of fabricating a semiconductor integrated circuit device according to claim 20, wherein said gas atmosphere at the time of said etching is substantially the same as said gas atmosphere of said step of applying said dry etching treatment (a).

22. A semiconductor integrated circuit device comprising:
(a) a semiconductor substrate region having a first main plane;
(b) a bottom electrode formed on said main plane either directly or through at least one film, and constituting a part of a capacitor of a memory cell;
(c) an information storage dielectric layer formed of a high dielectric or ferroelectric material, and constituting a part of said capacitor of said memory cell formed over said bottom electrode; and
(d) a top electrode formed of Ir or IrO₂, and constituting a part of said capacitor of said storage cell formed over said information storage dielectric layer;
wherein a pattern side surface of said top electrode has a taper expanding downward, and the angle of inclination of the slope is not greater than 80°.

23. A semiconductor integrated circuit device according to claim 22, wherein said information storage dielectric layer is formed of a high dielectric or ferroelectric substance having a perovskite structure or a structure equivalent to said perovskite structure.

24. A semiconductor integrated circuit device according to claim 23, wherein the angle of inclination of said slope is not greater than 75°.

25. A semiconductor integrated circuit device according to claim 24, wherein said information storage dielectric layer is formed of PZT, PLT or PLZT.

26. A method of fabricating a semiconductor integrated circuit device comprising the steps of:
(a) applying a dry etching treatment to a first film formed of a platinum metal or its oxide as a main constituent element over a first major surface of a semiconductor wafer having a photoresist formed and patterned thereon, in a gas atmosphere containing a chlorine gas as a main component of an etching gas; and
(b) applying over-etching to said first film by removing a side wall adhesion film adhering during the etching process of said first film in a gas atmosphere containing a chlorine gas as a main component of an etching gas and oxygen as an additional gas, while an underlying second film formed of a material different from the material of said first film is being etched beyond said first film.

27. A method of fabricating a semiconductor integrated circuit device comprising the steps of:
(a) applying a dry etching treatment to a first film formed of a platinum group metal or its oxide as a main constituent element over a first major surface of a semiconductor wafer having a photoresist formed and patterned thereon, in a gas atmosphere of an etching gas containing a chlorine gas and oxygen added thereto; and
(b) applying over-etching to said first film by removing a side wall adhesion film adhering during said etching process of said first film while an underlying second film made of a material different from that of said first film is being etched beyond said first film.

28. A method of fabricating a semiconductor integrated circuit device comprising the step of:
applying a dry etching treatment to a first film formed of Ir or IrO₂ as a main constituent element over a first major surface of a semiconductor wafer having a photoresist film formed and patterned thereon, in a gas atmosphere of an etching gas containing a chlorine gas and oxygen added thereto.

29. A semiconductor integrated circuit device comprising:
(a) a semiconductor substrate region having a first major surface;
(b) a bottom electrode formed of Ru or Ru0₂ and constituting a part of a capacitor of a memory cell formed on said first major surface either directly or through at least one film;
(c) an information storage dielectric layer formed of PZT or ferroelectric substance equivalent to PZT, and constituting a part of said capacitor of said memory cell formed over said bottom electrode; and
(d) a top electrode formed of Ir or IrO₂, and constituting a part of said capacitor of said memory cell formed over said information storage dielectric layer.
